(19) United States
(12) Patent Application Publication
(10) Pub. No.: US 2014/0120711 A1
(43) Pub. Date: May 1, 2014

(54) METHOD OF FORMING METAL GATE

(71) Applicant: UNITED MICROELECTRONICS CORP., Hsinchu (TW)

(72) Inventors: Min-Chuan Tsai, New Taipei City (TW); Hsin-Fu Huang, Tainan City (TW); Chi-Mao Hsu, Tainan City (TW); Tsun-Min Cheng, Changhua County (TW); Chien-Hao Chen, Yunlin County (TW); Wei-Yu Chen, Tainan City (TW); Chi-Yuan Sun, Yunlin County (TW)

(73) Assignee: UNITED MICROELECTRONICS CORP., Hsinchu (TW)

(21) Appl. No.: 13/661,998

(22) Filed: Oct. 26, 2012

(51) Int. Cl. H01L 21/283

(52) U.S. Cl. 438/592; 257/E21.159

(57) ABSTRACT

Provided is a method of forming a metal gate including the following steps. A dielectric layer is formed on a substrate, wherein a gate trench is formed in the dielectric layer and a gate dielectric layer is formed in the gate trench. A first metal layer is formed in the gate trench by applying a AC bias between a target and the substrate during physical vapor deposition. A second metal layer is formed in the gate trench by applying a DC bias between the target and the substrate during physical vapor deposition.

### BACKGROUND

1. Technical Field

The present invention relates to semiconductor fabrication, and more particularly, to a method of forming a metal gate.

2. Description of Related Art

Metal oxide semiconductor field effect transistor (MOS) is a basic structure widely applied to various semiconductor devices such as memory devices, image sensors, and display devices. To meet the demand of lighter, thinner, and smaller electronic devices, the size of CMOS is continuously shrunk, and the technology involving high-k (high dielectric constant) dielectric layer with a metal gate (HK/MG) has been extensively studied and progressively developed. To provide an adequate interfacial effect between the metal gate and the gate dielectric layer, different work function metal layers are provided between the corresponding metal gates and high-k gate dielectric layers for NMOS and PMOS. A metal layer is then deposited on the work function metal layer to complete the formation of a HK/MG MOS.

The deposition of the work function metal layer or the subsequent metal layer, however, may easily produce an overhang at the gate trench openings. With the presence of the overhang, the quality of the subsequent metal deposition may be deteriorated. For example, there may be voids forming in the metal gate, and the reliability of the devices is therefore affected.

### SUMMARY

An embodiment of the present invention provides a method of forming a metal gate including the following steps. A dielectric layer is formed on a substrate, wherein a gate trench is formed in the dielectric layer and a gate dielectric layer is formed in the gate trench. A first metal layer is formed in the gate trench by applying a AC (alternating current) bias between a target and the substrate during physical vapor deposition. A second metal layer is formed in the gate trench by applying a DC (direct current) bias between the target and the substrate during physical vapor deposition.

In an embodiment, the method of forming a metal gate further includes forming a wetting layer in the gate trench before the formation of the first metal layer.

In an embodiment, the wetting layer includes titanium or cobalt.

In an embodiment, the method of forming a metal gate further includes forming a first work function metal layer before the formation of the first metal layer.

In an embodiment, the first work function metal layer includes titanium aluminide (TiAl), zirconium aluminide (ZrAl), tungsten aluminide (WAl), tantalum aluminide (TaAl) or hafnium aluminide (HfAl).

In an embodiment, the method of forming a metal gate further includes forming a top barrier metal layer after the formation of the first work function metal layer and before the formation of the first metal layer.

In an embodiment, the top barrier metal layer includes titanium nitride.

In an embodiment, the first metal layer is in direct contact with the top barrier metal layer.

In an embodiment, the method of forming a metal gate further includes forming an etch stop layer before the formation of the first work function metal layer.

In an embodiment, the etch stop layer includes tantalum nitride (TaN).

In an embodiment, the method of forming a metal gate further includes forming a bottom barrier metal layer before the formation of the etch stop layer.

In an embodiment, the bottom barrier metal layer includes titanium nitride.

In an embodiment, the method of forming a metal gate further includes forming a second work function metal layer after the formation of the etch stop layer and before the formation of the first work function metal layer.

In an embodiment, the second work function metal layer includes TiN, TaN, titanium carbide (TiC), tantalum carbide (TaC), tungsten carbide (WC), or aluminum titanium nitride (TiAlN).

In an embodiment, the first metal layer includes Al, Cu, W, TiAl, or titanium aluminum oxide (TiAlO).

In an embodiment, the second metal layer includes Al, Cu, W, TiAl, or titanium aluminum oxide (TiAlO).

In an embodiment, the target includes aluminium, tungsten, or copper.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1H are schematic cross-sectional drawings illustrating a method of forming a metal gate according to several embodiments of the present invention.

### DESCRIPTION OF EMBODIMENTS

Reference will now be made in detail to the embodiments of the invention, examples of which are illustrated in the accompanying drawings. Wherever possible, the same reference numbers are used in the drawings and the description to refer to the same or similar elements.

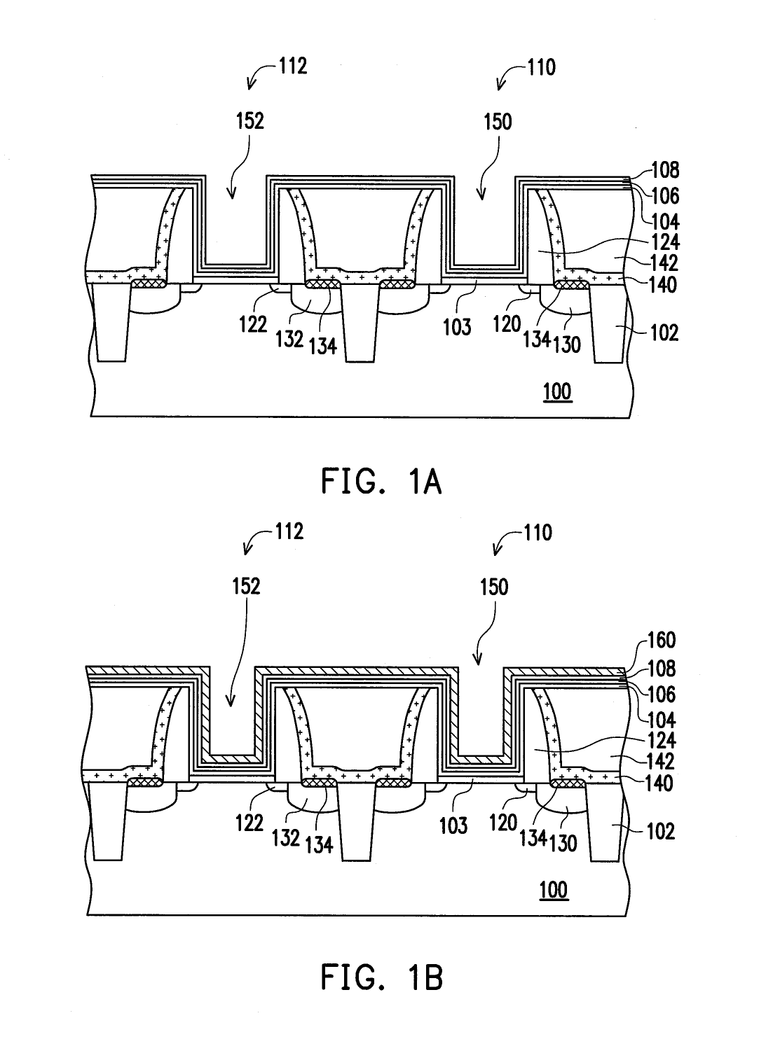

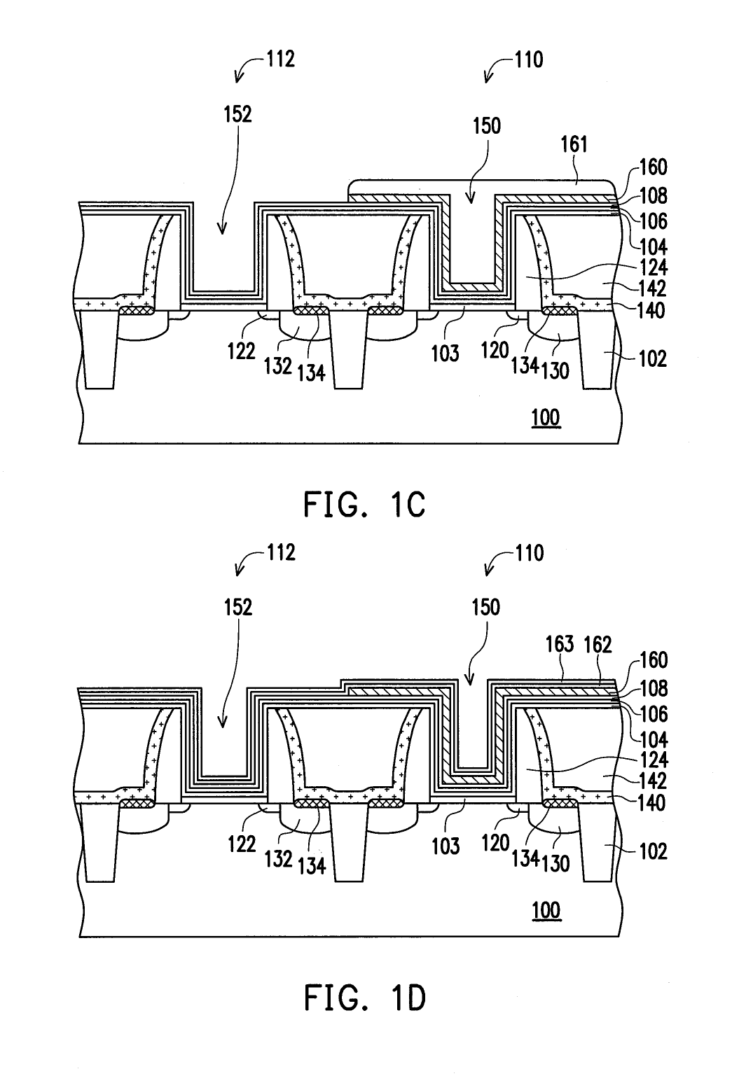

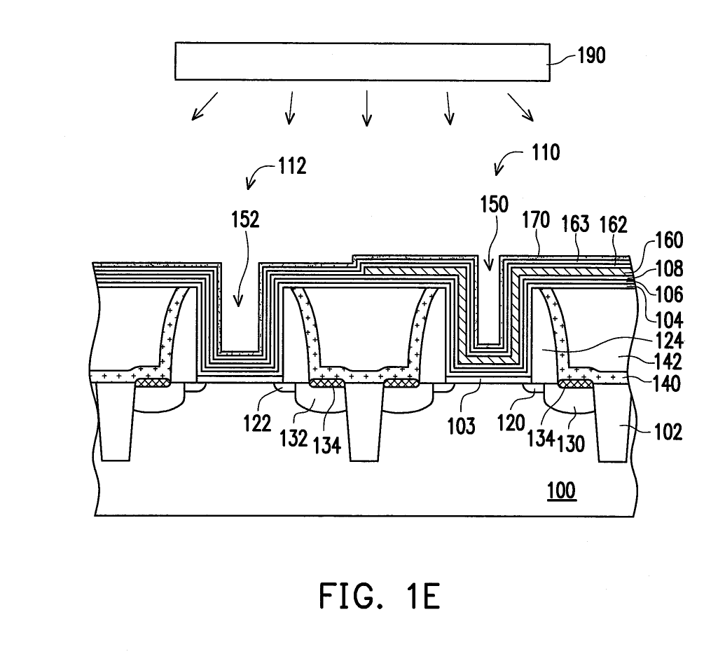

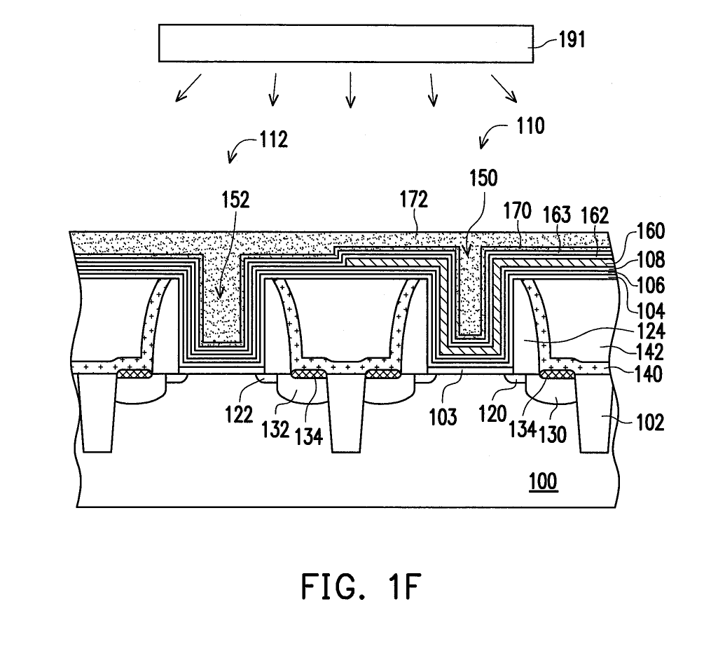

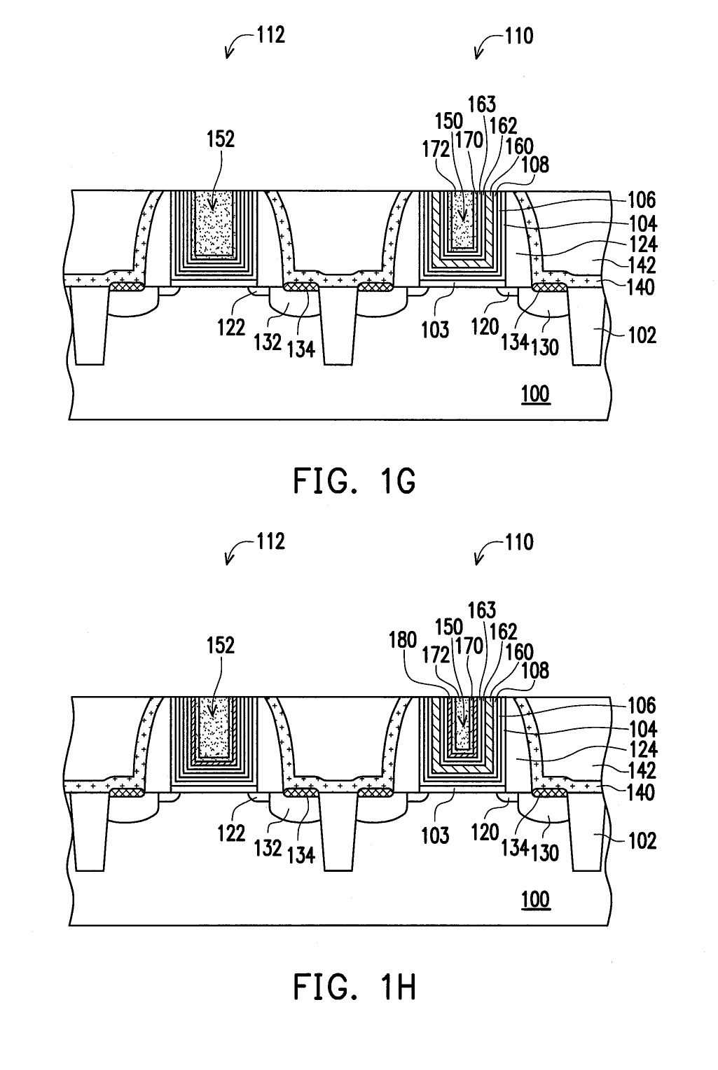

FIGS. 1A-1G are schematic cross-sectional drawings illustrating a method of forming a metal gate according to an embodiment of the present invention.

Referring to FIG. 1A, a substrate 100 such as silicon substrate, silicon-containing substrate, or silicon-on-insulator (SOI) substrate is provided. The substrate 100 has a first device region 110 and a second device region 112 formed thereon. A shallow trench isolation (STI) structure 102 is formed in the substrate 100 between the first device region 110 and the second device region 112, providing electrical isolation therebetween. In the present embodiment, a PMOS may be formed in the first device region 110 and a NMOS may be formed in the second device region 112 in the subsequent fabrication process. That is, the first device region 110 and the second device region 112 are “complementary.”

Continue referring to FIG. 1A, a first gate trench 150 and a second gate trench 152 are respectively formed in the first device region 110 and the second device region 112. Each of the first device region 110 and the second device region 112 includes a gate dielectric layer 104, a bottom barrier metal layer 106 and an etch stop layer 108. Furthermore, the first device region 110 includes a first lightly doped drain (LDD) 120, a first source/drain 130 and a spacer 124; the second device region 112 includes a second LDD 122, a second source/drain 132 and a spacer 124. Additionally, an optional salicide layer 134 is formed on each of the first source/drain 130 and the second source/drain 132.

Before the formation of the first gate trench 150 and the second gate trench 152, a contact etch stop layer (CESL) 140 and an inter-layer dielectric (ILD) layer 142 are sequentially formed. The process steps and material choices for the abovementioned elements are well-known to those skilled in the art, and thus details are omitted here for brevity. Furthermore, selective strain scheme (SSS) can be used in the present embodiment. For example, a selective epitaxial growth (SEG) method can be used to form the first source/drain 130 and the second source/drain 132.

The gate dielectric layer 104 can be a silicon oxide (SiO₂) layer, a high-k gate dielectric layer with a dielectric constant greater than 4, or the combination thereof. The high-k material with a dielectric constant greater than 4 can be metal oxide, such as rare earth metal oxide. The high-k material can be selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT), and barium strontium titanate (BaₓSr₁₋ₓTiO₃, BST), wherein x is between 0 and 1. Additionally, an interfacial layer 103 can be formed between the high-k gate dielectric layer 104 and the substrate 100. The interfacial layer 103 can include silicon oxide. The bottom barrier metal layer 106 can include titanium nitride (TiN), and the forming method thereof includes performing an atomic layer deposition (ALD) process. The etch stop layer 108 can include tantalum nitride (TaN), and the forming method thereof includes performing an ALD process.

The present embodiment can be integrated with the “high-k last” process. That is, the high-k gate dielectric layer is formed after the formation and removing of a dummy gate. Specifically, the method includes forming an interfacial material layer on the substrate 100, and then forming a dummy gate layer. The dummy gate layer can include polysilicon, but the present invention is not limited thereto. Thereafter, the interfacial material layer and the dummy gate layer are patterned, so as to form a patterned interfacial material layer and a dummy gate. Afterwards, a CESL 140 and a ILD layer 142 are formed, and a planarization process is performed to remove a portion of the CESL 140 and a portion of the ILD layer 142 to expose the dummy gate in each of the first device region 110 and the second device region 112. Then, a suitable etching process is performed to remove the dummy gate in each of the first and second device regions 110 and 112, and thus a first gate trench 150 and a second gate trench 152 are simultaneously formed in the first device region 110 and the second device region 112. The interfacial material layer can be optionally removed and an interfacial layer 103 is then formed. A high-k gate dielectric layer 104 is thereafter formed on the substrate 100. A bottom barrier metal layer 106 and/or an etch stop layer 108 are afterwards formed.

Referring to FIG. 1B, after forming the etch stop layer 108, a work function metal layer 160 is formed on the substrate 100 to fill in the first gate trench 150 and the second gate trench 152. The material of the work function metal layer 160 can be selected depending on the type of semiconductor device to be formed in the first device region 110. In the present embodiment (a PMOS is formed in the first device region 110 in the subsequent process), the work function metal layer 160 includes TiN, TaN, titanium carbide (TiC), tantalum carbide (TaC), tungsten carbide (WC), or aluminum titanium nitride (TiAlN), but the present invention is not limited thereto. In addition, the work function metal layer 160 can be a single-layered structure or a multi-layered structure. The method of forming the work function metal layer 160 includes performing a chemical vapor deposition (CVD) process, a physical vapor deposition (PVD) process or an ALD process.

Referring to FIG. 1 C, the work function metal layer 160 on the second device region 112 is removed so that the etch stop layer 108 in the second gate trench 152 is exposed. The work function metal layer 160 can be removed by a conventional etching process in which a photoresist 161 is formed in advance on the work function metal layer 160 on the first device region 110.

Referring to FIG. 1D, after removing the photoresist 161, a work function metal layer 162 and a top barrier metal layer 163 are sequentially formed on the substrate 100. The work function metal layer 162 contacts with the etch stop layer 108 in the second gate trench 152, and contacts with the work function metal layer 160 in the first gate trench 150. The material of the work function metal layer 162 can be selected depending on the type of semiconductor device to be formed in the second device region 112. In the present embodiment (an NMOS is formed in the second device region 112 in the subsequent process), the work function metal layer 162 includes titanium aluminide (TiAl), zirconium aluminide (ZrAl), tungsten aluminide (WAl), tantalum aluminide (TaAl) or hafnium aluminide (HfAl), but the present invention is not limited thereto. In addition, the work function metal layer 162 can be a single-layered structure or a multi-layered structure. The work function metal layer 162 can be formed through a CVD process, a PVD process, or an ALD process. The top barrier metal layer 163 can include TiN, and the forming method thereof includes performing an ALD process, but the present invention is not limited thereto.

Referring to FIG. 1E, a first metal layer 170 is formed on the substrate 100 by physical vapor deposition. In the present embodiment, the physical vapor deposition includes a sputtering process, and the sputtering process is performed by applying a AC bias between the target 190 and the substrate 100. The first metal layer 170 includes Al, Cu, W, TiAl, or titanium aluminum oxide (TiAlO). The target 190 includes aluminium, titanium, tungsten, or copper, for example. This “AC-mode” of sputtering process guarantees a better step coverage as compared to the “DC-mode” of sputtering process. Specifically, the sidewalls of the gate trenches 150 and 152 can be uniformly covered by the first metal layer 170 in this step. The common issue of overhang formation at the opening of the gate trench can be avoided. Further, the metal layer 170 may serve as a seed layer for the subsequent filling process of the gate trenches 150 and 152.

Referring to FIG. 1F, a second metal layer 172 is formed on the substrate 100. The second metal layer 172 includes Al, Cu, W, TiAl, or titanium aluminum oxide (TiAlO). The second metal layer 172 is formed by physical vapor deposition. The physical vapor deposition includes a sputtering process, and the sputtering process is performed by applying a DC bias between the target 191 and the substrate 100. The target 191 and the target 190 can be made of the same material. In other word, the first metal layer 170 and the second metal layer 172 can be made of the same material. The DC-mode of sputtering process has a significantly improved throughput as compared to the AC-mode of sputtering process. By combing the AC-mode and the DC-mode of the sputtering process, it is possible to reduce the void formation in the metal gates (i.e. portions of the first and second metal layers 170 and 172 filling in the first and second gate trenches 150 and 152) while maintaining a satisfactory process throughput.

Referring to FIG. 1G, a planarization process such as a chemical mechanical polishing (CMP) process is performed to remove the unnecessary first metal layer 170, second metal layer 172, the top barrier metal layer 163, the work function metal layers 162 and 160 on the ILD layer 142. Consequently, metal gates (the remaining portion of the first and second metal layers 170 and 172 in the gate trenches 150 and 152) are obtained. In addition, the ILD layer 142 and the CESL 140 can be selectively removed and sequentially reformed on the substrate 100 for improving the electric performance of the semiconductor devices. The CMP process is well-known to those skilled in the art, and the process details are omitted for brevity.

Referring to FIG. 1H, in another embodiment, before the formation of the first metal layer 170, a wetting layer 180 can be formed in the gate trenches 150 and 152 so as to facilitate the filling process of the first and the second metal layer 170 and 172. The wetting layer 180 can include titanium or cobalt and can be formed by a PVD process. The present invention, however, is not limited thereto. It is possible to complete the formation of metal gate without depositing the wetting layer 180.

The present invention has been described in the context of a “high-k last” process thus far. However, the present invention is not limited thereto. In other embodiments, the present invention may be integrated with a “high-k first” process. The process flows are similar except that the high-k dielectric layer and the bottom barrier metal layer are formed prior to the formation of the dummy gate. The similar details thus will not be reiterated here.

Accordingly, embodiments of present invention provide a method of forming a metal gate in which filling of the gate trench is carried out by a two step process. In the first step, metal such as aluminium is deposited into the gate trench by sputtering with a AC bias applying between the sputter target and the substrate. In the second step, the gate trench is filled with metal material by sputtering with a DC bias applying between the target and the substrate. The first step provides a better sidewall coverage and the second step ensures an adequate throughput.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of forming a metal gate comprising:
forming a dielectric layer on a substrate, wherein a gate trench is formed in the dielectric layer and a gate dielectric layer is formed in the gate trench;
forming a first metal layer in the gate trench by applying a AC bias between a target and the substrate during physical vapor deposition, and
forming a second metal layer in the gate trench by applying a DC bias between the target and the substrate during physical vapor deposition.

2. The method of claim 1, further comprising forming a wetting layer in the gate trench before forming the first metal layer.

3. The method of claim 2, wherein the wetting layer comprises titanium or cobalt.

4. The method of claim 1, further comprising forming a first work function metal layer before forming the first metal layer.

5. The method of claim 4, wherein the first work function metal layer comprises titanium aluminide (TiAl), zirconium aluminide (ZrAl), tungsten aluminide (WAl), tantalum aluminide (TaAl) or hafnium aluminide (HfAl).

6. The method of claim 4, further comprising forming a top barrier metal layer after forming the first work function metal layer and before forming the first metal layer.

7. The method of claim 6, wherein the top barrier metal layer comprises titanium nitride.

8. The method of claim 6, wherein the first metal layer is in direct contact with the top barrier metal layer.

9. The method of claim 6, further comprising forming an etch stop layer before forming the first work function metal layer.

10. The method of claim 9, wherein the etch stop layer comprises tantalum nitride (TaN).

11. The method of claim 9, further comprising forming a bottom barrier metal layer before forming the etch stop layer.

12. The method of claim 11, wherein the bottom barrier metal layer comprises titanium nitride.

13. The method of claim 9, further comprising forming a second work function metal layer after forming the etch stop layer and before forming the first work function metal layer.

14. The method of claim 13, wherein the second work function metal layer comprises TiN, TaN, titanium carbide (TiC), tantalum carbide (TaC), tungsten carbide (WC), or aluminum titanium nitride (TiAlN).

15. The method of claim 1, wherein the first metal layer comprises Al, Cu, W, TiAl, or titanium aluminum oxide (TiAlO).

16. The method of claim 1, wherein the second metal layer comprises Al, Cu, W, TiAl, or titanium aluminum oxide (TiAlO).

17. The method of claim 1, wherein the target comprises aluminium, tungsten, or copper.
